(19) United States
(12) Patent Application Publication
(10) Pub. No.: US 2019/0338561 A1
(43) Pub. Date: Nov. 7, 2019

(54) MOTOR VEHICLE OPERATING DEVICE HAVING A CENTERED ACTUATING ELEMENT

(71) Applicant: AUDI AG, Ingolstadt (DE)

(72) Inventor: Michael WACHINGER, Winkelhausen (DE)

(73) Assignee: AUDI AG, Ingolstadt (DE)

(21) Appl. No.: 15/741,165

(22) PCT Filed: Apr. 15, 2016
(86) PCT No.: PCT/EP2016/000618

§ 371 Date: Dec. 29, 2017

(30) Foreign Application Priority Data
Jul. 2, 2015 (DE) 10 2015 008 573.5

(51) Int. Cl. E05B 47/00; E05B 79/04

(52) U.S. Cl. CPC E05B 47/0001; E05B 2047/0014; E05B 2047/0048; E05B 79/04

(57) ABSTRACT

A movably mounted actuation element and an actuator apparatus for producing a feedback movement of the actuation element depending on an excitation signal are included in an operating apparatus for a motor vehicle. The actuation element has a defined rest position in the housing. The actuation element is arranged in such a rest position in the non-actuated state in which at least one centering element blocks the feedback movement. The actuation element carries out an evasive movement in a direction aligned obliquely or perpendicular to the direction of the feedback movement in the case of an application of an operating force on part of the user, the actuation element switching from the rest position into a released position, in which it is released for the feedback movement by the at least one centering element, as a result of the evasive movement.

### CROSS REFERENCE TO RELATED APPLICATIONS

This application is a U.S. national stage of International Application No. PCT/EP2016/000618, filed on Apr. 15, 2016. The International Application claims the priority benefit of German Application No. 10 2015 008 573.5 filed on Jul. 2, 2015. Both the International Application and the German Application are incorporated by reference herein in their entirety.

### BACKGROUND

Described herein is an operating apparatus for a motor vehicle, having an actuation element which is movably mounted in respect of a housing of the operating apparatus and which has a contact surface for a user. By way of example, the actuation element can be configured as a key or as a key strip. An actuator apparatus for producing a feedback movement of the actuation element is provided in order to produce a haptic feedback at the operating surface. Also described herein is a motor vehicle having the operating apparatus.

An actuation element whose operating surface can be excited by an actuator device must be arranged, to this end, in such a movable manner in the housing of the operating apparatus that the feedback movement can be carried out by the actuation element without striking the housing in the process. As a rule, a circumferential gap is provided around the actuation element to this end. This gap then must be covered by cladding or tiling. The reason for this is that the gap profile or the gap dimension may become irregular as the operating surface must have a free-swinging embodiment and be able to displace, for example by being tapped. However, on account of the necessary cladding, the operating surface always lies in a depression, and so dust and/or dirt particles can also easily collect on the operating surface.

In the case of an operating apparatus having an actuation element which can be excited to a feedback movement by way of an actuator device, it is consequently difficult to set a gap dimension of a gap or a joint between the actuation element and the housing of the operating apparatus on account of the demanded mobility of the actuation element.

U.S. Patent Application Publication No. 2006/0266633 A1 has described a flip switch for a motor vehicle, which does not protrude beyond a plane cladding face surrounding the switch in either the non-actuated or actuated state. To this end, an axis of rotation about which the switch rotates during actuation is displaced into a region next to the switch.

U.S. Patent Application Publication No. 2007/0227870 A1 has described a lamp switch which has a knob that need not necessarily be pressed centrally for switching the lamp, but which is also applied by an operating force at an edge and, as a result of this, only needs to be tilted. Here, the lamp can also be switched by the tilting. When it is not actuated, the knob is held in a rest position by a spiral spring.

German Patent Application Publication No. 1930465 U has described an electric pushbutton which has an actuation element that is pressed into a rest position by a spiral spring and held there by a screw, the screw representing an abutment element which restricts a spring travel of the spiral spring.

### SUMMARY

An aspect of the disclosure is based on nevertheless setting a defined rest position in an operating apparatus of a motor vehicle despite mobility of the actuation element provided for a feedback movement.

Described herein is an operating apparatus for a motor vehicle. The operating apparatus has an actuation element which is movably mounted in respect of a housing of the operating apparatus and which has a contact surface for an operation by a user. By way of example, the actuation element can be configured as a key or key strip or touchpad (touch-sensitive operating area). A sensor device is designed to produce a sensor signal depending on contact of the contact surface on part of the user and/or approach to the contact surface on part of the user. A control device is configured in such a way that it produces a control signal for at least one appliance of the motor vehicle depending on the sensor signal and, with the control signal, also an excitation signal for an actuator device. To this end, the control device may have, for example, a microcontroller or a microprocessor.

The actuator device is designed to produce a feedback movement of the actuation element depending on the excitation signal. Expressed differently, a user may touch the actuation element; this is signaled by the sensor device by using the sensor signal. To this end, the sensor device may have, for example, a capacitive proximity sensor or an arrangement made of a plurality of capacitive proximity sensors. On the basis of the sensor signal, the control device identifies the contact and produces the control signal for the at least one appliance. By way of example, an infotainment system (information-entertainment system), a climate control, a telephone system or a suspension control may be provided in each case as an appliance. The control device moreover produces the excitation signal in order to signal to the user that a control signal was emitted. Depending on the excitation signal, the actuator device causes or produces a feedback movement of the actuation element. By way of example, a vibration of the actuation element or a one-time deflection of the actuation element may be provided as feedback movement, with the one-time deflection then being perceived by the user as a jolt or as clicking. The deflection has a duration of, for example, less than 1 second, or for example, less than 500 ms.

In order now to keep the actuation element in a predetermined rest position when not being operated, the actuation element is arranged in a rest position in the non-actuated state in which at least one centering element blocks the feedback movement. Expressed differently, the actuation element is clamped or held by the at least one centering element when the actuation element is in the non-actuated state, where it is not applied by the user by way of a contact force and/or where it is not deflected, such that the actuation element cannot carry out the feedback movement. By selecting the form of each centering element, it is consequently possible to bring the actuation element into a predetermined rest position, or hold it there, such that, for example, a gap dimension of a gap or of a joint is also set accordingly, the gap or joint being provided between the actuation element and the housing.

In order nevertheless to facilitate the feedback movement, the actuation element switches its position in the case of an application of an operating force on the contact surface on part of the user. On account of the operating force, the actuation element carries out an evasive movement aligned obliquely or perpendicular to the direction of the feedback movement, the actuation element switching from the rest position into a released position, in which it is released for the feedback movement by the at least one centering element, as a result of the evasive movement. Expressed differently, the actuator device can impart the feedback movement onto the actuation element only if the actuation element has switched from the rest position into the released position by way of the evasive movement. By way of example, the centering element can be configured as a frame or ring which surrounds the actuation element in the rest position. The actuation element can then carry out the feedback movement after it has moved out of the frame.

The advantage arising from the operating apparatus described herein is that, in the non-actuated state, the actuation element is held or anchored in the rest position by the at least one centering element and it is possible to set a predeterminable gap dimension or a predetermined position of the actuation element in the operating apparatus as a result thereof. The actuation element only becomes so mobile that it carries out the feedback movement when moved by the actuator apparatus once the actuation element is actuated by way of a user applying an operating force on the actuation element and thereby moving or deflecting the latter from the rest position. The at least one centering element can be fastened to the housing or to the actuation element.

The operating apparatus described herein also includes optional developments, with additional advantages arising from the features thereof.

In conjunction with the formation of a gap or a joint with a predeterminable gap dimension or joint dimension, provision is made of a gap surrounding or encompassing the actuation element, or of a corresponding joint, between the actuation element and the housing. Moreover, provision is made for the operating surface to terminate flush and/or in a planar fashion with a housing edge of the housing. Expressed differently, this avoids the operating surface being situated in a depression which is formed by circumferential cladding or tiling.

According to a development, provision is made for an elastically deformably embodied restoring device to push or pull the actuation element to the rest position with a restoring force. By way of example, to this end, the restoring device may have a spring which, for example, can be configured as a spiral spring or leaf spring or disk spring. By way of example, the restoring device can be formed on the basis of a plastic or a metal. For example, the restoring device and the at least one centering element are different. The advantage arising from the development is that the actuation element is pushed or pulled back into the rest position via the restoring force and, in the process, the restoring force can be selected to be so large that the actuation element and the at least one centering element are pressed together or clamped to one another. As a result of this, there is a particularly secure seat of the actuation element in the rest position.

According to a development, the at least one centering element, in the rest position of the actuation element, is arranged between the actuation element and a cladding of the housing surrounding the actuation element. Expressed differently, the actuation element is directly anchored by way of the at least one centering element. As a result of this, the tolerance chain when manufacturing the operating apparatus is minimized in respect of the setting of the rest position. This is because the at least one centering element directly anchors the actuation element.

According to a development, a joint or a gap is formed between the actuation element and the housing, and the at least one centering element is arranged at a distance greater than zero from the contact surface in the joint or in the gap, or lowered therein. Expressed differently, the at least one centering element is not visible from the outside because it is lowered into the joint or the gap. The distance is for example more than 2 millimeters, or for example more than 3 millimeters.

As an alternative to a centering element which is arranged directly at the actuation element in the rest position, provision is made according to a development for the actuation element to be fastened to a carrier element via a support apparatus. By way of example, the carrier element can be configured as a plate. By way of example, the support apparatus can be configured on the basis of at least one leaf spring or at least one cylindrical helical coiled spring or at least one rod. Here, the carrier element is movably mounted in the housing together with the actuation element. Expressed differently, the carrier element is also moved if the actuation element is moved. Now, the at least one centering element is not arranged in the rest position directly at the actuation element but between the carrier element and the housing. Expressed differently, the actuation element is indirectly anchored in the rest position via the carrier element by using the at least one centering element. The advantage arising herefrom is that it is possible to provide a deeper gap or deeper joint around the actuation element. For example, the at least one centering element is arranged more than 1 centimeter, or for example more than 2 centimeters, deep in the gap or in the joint within the housing. Expressed differently, the centration by way of the carrier element is advantageous in that the at least one centering element is not visible at the surface. In the rest position, the carrier element is captured by the centering element. By way of a support apparatus, which has at least one leaf spring or at least one cylindrical helical coiled spring, a relative movement between the actuation element and the carrier element is moreover possible such that the actuation element can carry out the feedback movement independently of the carrier element as well. Nevertheless, an operating force can also be transferred in each case from the actuation element to the carrier element by way of a leaf spring and a cylindrical helical coiled spring. The holding grip or the anchoring of the centering element in relation to the carrier element is restricted to the rest position. When the actuation element is actuated, a clearance arises in the released position in order to keep friction as low as possible.

According to a development, the actuation element is not configured as an individual key but as a touchpad or as a key strip. Here, the sensor device is configured in such a way that it signals by way of the sensor signal a contact site, at which the user touches the operating surface. Expressed differently, the contact signal distinguishes between at least two different contact sites, for example between more than two. In conjunction with a touchpad, this may specify, for example, a coordinate of the contact site on the operating surface. In conjunction with a key strip, the sensor signal can indicate which one of the keys forming the key strip was touched. The advantage arising from the development is that the actuator device provides the haptic feedback in the form of a feedback movement for the entire touchpad or for all keys of the key strip but only a single actuator device is required to this end. By way of example, the actuator device may have an electric motor or an electromagnet or a piezo element, by which the actuation element is respectively put into the feedback movement, and the haptic feedback is produced in this manner for the entire actuation element.

According to a development, provision is made of a force sensor which produces a force signal that is correlated with an operating force applied to the actuation element. Here, the control device is configured in such a way that it only produces the control signal for the at least one appliance of the motor vehicle if the force signal signals an operating force that is greater than a predetermined threshold. Expressed differently, the user must not only contact the actuation element on the operating surface but must also exert a minimum force onto the operating surface as an operating force. The advantage arising herefrom is that an unwanted or inadvertent production of a control signal on account of random or inadvertent contact of the actuation element is avoided. The user has to deliberately apply the operating force, which is greater than the threshold, in order to effectuate a production of the control signal.

According to a development, the at least one centering element has an elastic material. By way of example, the material may be a foam, silicone or felt. The advantage arising herefrom is that the operating device can be sealed in the rest position of the actuation element by virtue of the at least one centering element surrounding or sealing or encompassing the actuation element over the entire circumference thereof. The at least one centering element also may be formed from a rigid material. For example, the at least one centering element may have an integral embodiment with the housing, for example as a continuation of a housing wall of the housing.

According to a development, the at least one centering element has, in each case, a sliding face for the actuation element, the sliding face being arranged at an angle with respect to the evasive movement. Expressed differently, a funnel or a guide is formed by the at least one centering element. If the actuation element is deflected into the released position and returns to the rest position thereafter, it is guided into the rest position by the sliding faces. This ensures a reliable restoration of the actuation element into the rest position. Expressed differently, jamming of the actuation element on the at least one centering element is avoided.

As already explained above, also described herein is a motor vehicle. The motor vehicle has at least one appliance which, in each case, may be one of the appliances already mentioned above. Moreover, embodiments of the operating apparatus described herein can be provided in the motor vehicle described herein, the operating apparatus being coupled to the at least one appliance and being designed to send its control signal to the at least one appliance.

The motor vehicle described herein is for example configured as a motorized vehicle, for example as an automobile.

### BRIEF DESCRIPTION OF THE DRAWINGS

These and other aspects and advantages will become more apparent and more readily appreciated from the following description of the exemplary embodiments, taken in conjunction with the accompanying drawings of which:

FIG. 1 is a schematic illustration of an embodiment of the motor vehicle described herein with an operating apparatus, in which an actuation element is arranged in the rest position;

FIG. 2 is the motor vehicle of FIG. 1, wherein the actuation element is arranged in a released position;

FIG. 3 is a schematic illustration of a further embodiment of the motor vehicle described herein with an operating apparatus, the actuation element of which is arranged in the rest position;

FIG. 4 is the motor vehicle of FIG. 3, wherein the actuation element is arranged in the released position; and

FIG. 5 is a schematic illustration of an operating apparatus having cladding and a depression formed by the cladding and an actuation element.

### DETAILED DESCRIPTION OF THE PREFERRED EMBODIMENT

Reference will now be made in detail to preferred embodiments, examples of which are illustrated in the accompanying drawings, wherein like reference numerals refer to like elements throughout.

Exemplary embodiments are explained below with reference to the drawings. In the exemplary embodiments, the described components of the embodiments respectively represent individual features, which should be considered independently of one another and which respectively also develop the disclosure independently of one another and which should consequently also be considered both individually or in a combination that differs from what is shown. Moreover, the described embodiments may also be complemented by further features already described.

In the drawings, functionally equivalent elements have been provided with the same reference sign in each case.

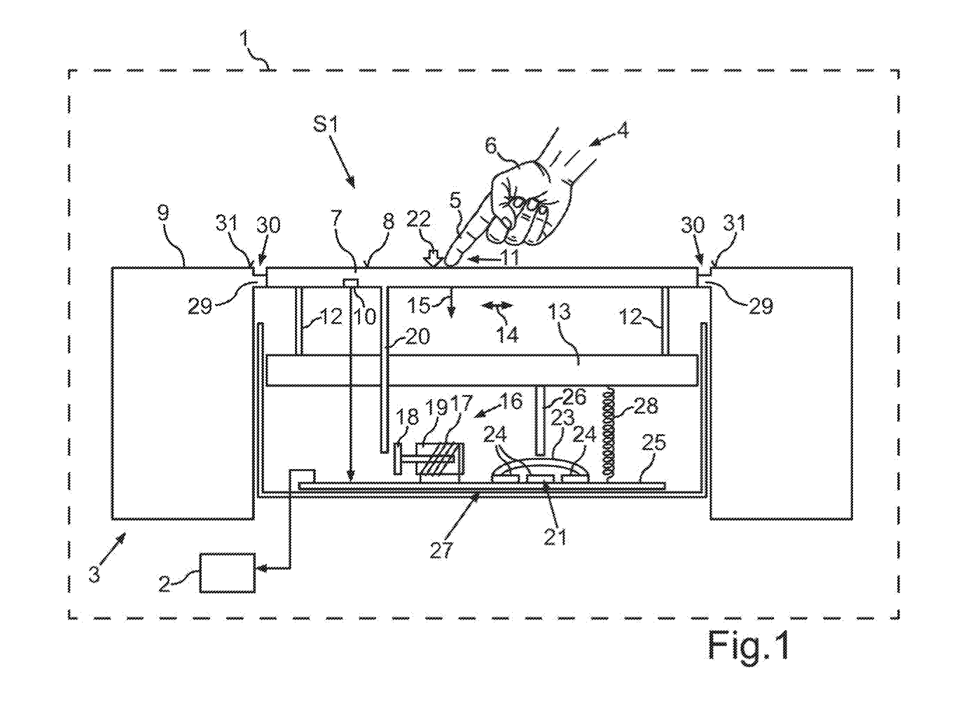

FIG. 1 shows a motor vehicle 1, which may be, for example, a motorized vehicle, for example an automobile. An appliance 2 and an operating apparatus 3 for the appliance 2 are illustrated. By way of example, the appliance 2 may be an infotainment system or a climate control or a telephone system or a suspension control. The operating apparatus 3 also may be coupled to a plurality of appliances. For the purposes of operating the appliance 2 by using the operating apparatus 3, a user 4 may contact an actuation element 7 at an operating surface 8 with a finger 5 of a hand 6 and press the actuation element 7 into a housing 9 of the operating apparatus 3 from a rest position S1 illustrated in FIG. 1.

Here, a sensor device 10 can capture a contact location or a contact site 11 of the finger 5 at the operating surface 8.

By way of example, the actuation element 7 may be configured as a touchpad, wherein a sensor matrix of the touchpad represents the sensor device 10. The actuation element 7 may also be configured as a key or key strip, wherein the sensor device 10 then distinguishes which key of the key strip was contacted by the finger 5.

The actuation element 7 may be fastened to a carrier element 13 via a support apparatus 12. By way of example, the support apparatus 12 may have one or more leaf springs which facilitate a movement of the actuation element 7 in relation to the carrier element 13 in a transverse direction 14 across, or perpendicular to, a deflection direction 15 of the actuation element 8 caused by an actuation. The deflection direction 15 is that direction in which the user pushes or presses the actuation element 8 into the housing 9 with the finger 5 during operation. By way of example, the carrier element 13 may be a plate which, for weight reduction purposes, may also have a honeycomb-shaped structure.

An actuator device 16 which, for example, may be formed on the basis of an electrical coil 17 that can produce an alternating force on a thermomagnetic or soft magnetic stamp 18, depending on a coil current, is provided for producing a haptic feedback movement along the transverse direction 14. A soft magnetic iron core 19 may be provided for amplifying the alternating force. The alternating force of the stamp 18 can be transferred onto the actuation element 7 via a lever element 20 such that the operating surface 8 vibrates or shakes or carries out an impulsive movement.

In addition to the sensor device 10, provision can be made of a force sensor 21, which captures an operating force 22 exerted onto the operating surface 8 by the finger 5. By way of example, the force sensor 21 may be formed on the basis of a disk spring 23 and electrical conductor tracks 24 of a printed circuit board 25. A force transfer from, for example, the carrier element 13 to the disk spring 23 may be provided by a rod element 26.

An electronic circuit of the printed circuit board 25 provides a control device 27 which is coupled to the sensor device 10, the actuator device 16, the force sensor 21 and the appliance 2.

The actuation element 7 and, therewith, the carrier element 13 are held in the rest position S1 illustrated in FIG. 1 by way of a restoring device 28. By way of example, the restoring device 28 may have a helical spring or leaf spring.

In the rest position S1, the actuation element 7 is secured in such a way that it cannot carry out a movement in the transverse direction 14, i.e., the movement in the transverse direction 14 is blocked. To this end, the actuation element 7 is anchored by a centering element 29 in respect of the transverse direction 14. By way of example, the centering element 29 may be formed by a web or a rib or a projection that surrounds the actuation element 7. By way of example, the centering element 29 can be formed on the housing 9 by using, for example, an injection molding method. Alternatively, the centering element 29 can be fastened to the actuation element 7. A joint 30, in which the centering element 29 may be arranged, is formed between the actuation element 7 and the housing 9. The operating surface 8 may terminate flush with, or be arranged at, an outer side or a cladding 31 of the housing 8.

The centering element 29 blocks or prevents the production of the above-described haptic feedback movement on the surface 8. To this end, the actuation element 7 is seated so securely in the rest position S1 that there is no change in the gap width of the joint 30 when, for example, the motor vehicle drives, not even on account of vibrations. For example, a tolerance or difference of the gap dimension along the entire joint 30 is less than 0.5 millimeters.

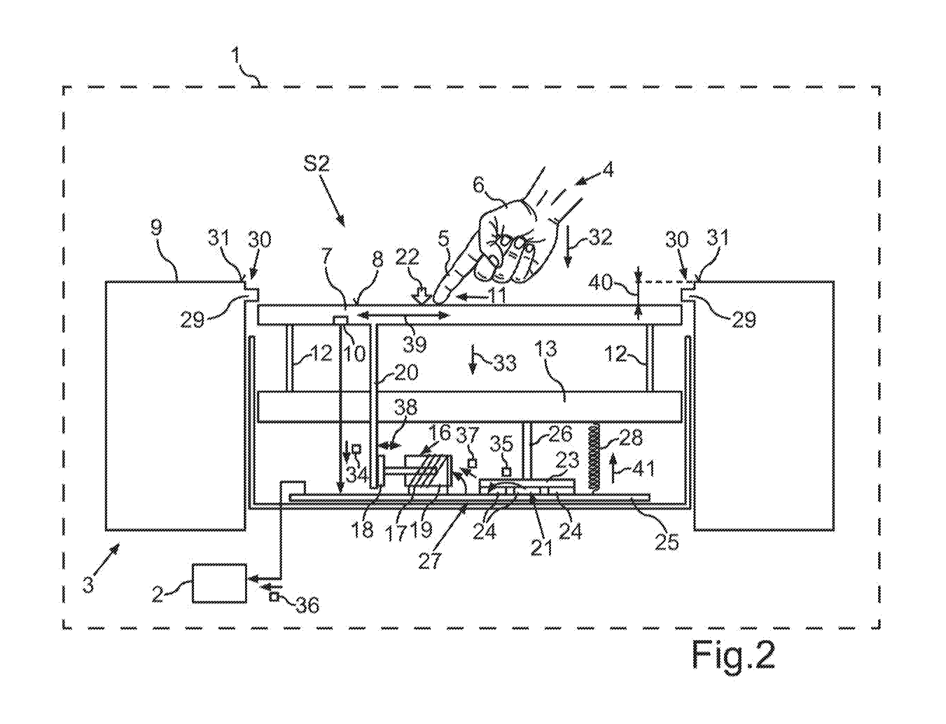

FIG. 2 elucidates an actuation process or an operating process of the operating apparatus 3 by the user 4.

FIG. 2 illustrates how the user 4 exerts the operating force 22 on the operating surface 8 by way of the finger 5 and, in the process, carries out an operating movement 32 such that the actuation element 7 carries out an evasive movement 33 following the operating force 22. By way of a sensor signal 34, the sensor device 10 signals that the operating surface 8 has been touched. If the operating force 22 is large enough, an evasive travel or a movement path of the actuation element 7 is so large that the force sensor 21 produces a force signal 35 which indicates that the operating force 22 is greater than a predetermined threshold. By way of example, the disk spring 23 may cause a short circuit between the conductor tracks 24 if the operating force 22 exceeds the threshold.

Depending on the sensor signal 34 and the force signal 35, the control device 27 produces a control signal 36 which is transmitted to the appliance 2. A function of the appliance 2 is activated in the appliance 2 as a result thereof. Moreover, the control device 27 produces an activation signal 37, by which the actuator device 16 is activated. By way of example, the activation signal 37 can be formed by an alternating current or by a current pulse. Then, the electrical coil 17 produces a corresponding vibration movement or pulse movement 38 of the stamp 18. The movement is transferred onto the actuation element 7 by the lever element 20, the actuation element effectuating the feedback movement 39 along the transverse direction 14 as a result thereof. A movement plane or movement direction of the feedback movement 39 is oblique or perpendicular to the movement direction of the evasive movement 33. For example, the movement direction of the feedback movement 39 is aligned, for example, in a coplanar fashion to the operating surface 8.

So that the actuation element 7 can move freely, i.e., so that it is even able to carry out the feedback movement 39, a movement travel or deflection travel 40 is so large that the centering element 29 has released the actuation element 7 for the feedback movement 39. Expressed differently, the deflection travel 40 is so large that the actuation element 7 moves from the rest position S1 into a released position S2 or it has switched to the latter. In the released position S2, the centering element 29 and the actuation element 7 are arranged without contact to one another. By contrast, the centering element 29 contacts the actuation element 7 in the rest position S1 and, as a result of this, keeps the latter securely in the rest position S1 in relation to the direction of the feedback movement 39.

As soon as the user removes the finger 5 from the actuation element 7, the actuation element 7, together with the carrier element 13, is moved back from the released position S2 into the rest position S1 by a restoring force 41 of the restoring device 28.

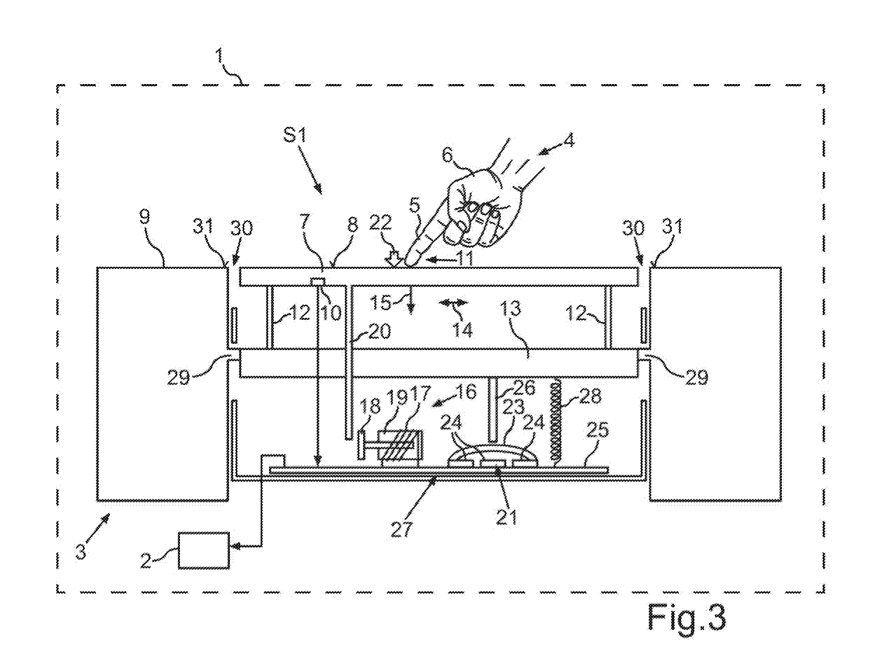

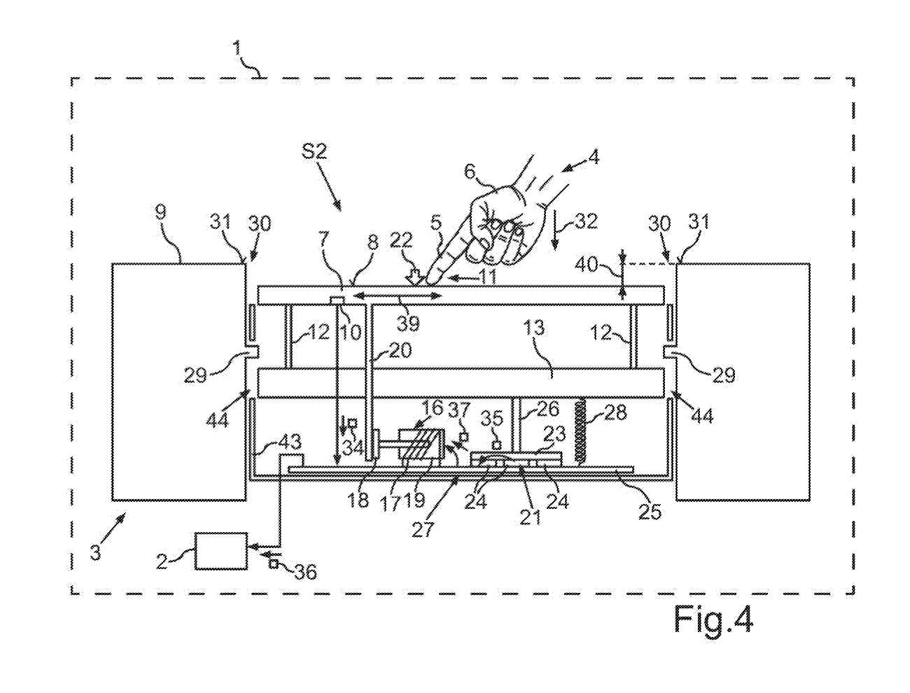

FIG. 3 and FIG. 4 illustrate an alternative configuration of the operating apparatus 3 in respect of the arrangement of the centering element 29. The remaining elements of the operating apparatus 3 may be configured in the same way as elucidated in FIG. 1 and FIG. 2. It is for this reason that the following presentation of the operating apparatus 3 according to FIG. 3 and FIG. 4 is restricted to the alternative arrangement of the centering element 29.

FIG. 3 illustrates the actuation element 7 in a rest position S1, in which the actuation element 7, however, is not held directly by a centering element but indirectly by way of the carrier element 7 and the support apparatus 12. Here, the support apparatus 12 may be provided by, for example, at least one rigid rod which anchors the actuation element 7 and the carrier element 13 in relation to one another. However, the support apparatus 12 may also have, for example, a leaf spring.

In the rest position S1, the carrier element 13 is anchored in a transverse direction 14 perpendicular to the actuation direction or deflection direction 15 by way of a centering element 29. As a result of this, it is possible to provide a deeper gap or a deeper joint 30.

As illustrated in FIG. 4, a deflection travel 40 of the operating surface 8 may be furthermore configured to be smaller during the actuation movement 32 than in the embodiments elucidated in FIG. 1 and FIG. 2. The reason for this is that the centering element 29 may be arranged at an edge of the carrier element 13 which is aligned toward the joint 30.

FIG. 4 moreover elucidates how the user produces the sensor signal 34 and the force signal 35 with the finger 5 by exerting the operating force 22 on the operating surface 8 and how the control device 27 produces the control signal 36 and, with the control signal 36, the activation signal 37 as a result thereof. As a result of this, the actuation element 7 is moved by using the actuator device 16, and so the actuation element carries out the feedback movement 39. In the released position S2 illustrated in FIG. 4, the centering element 29 contacts neither the actuation element 7 nor the carrier element 13. By contrast, the carrier element 13 is contacted by the centering element 29 in the rest position S1.

In order to facilitate a movement of the carrier element 13 in the released position S2, a housing shell of the housing 9 may have a recess 44, into which the carrier element 13 can plunge when carrying out the feedback movement 39.

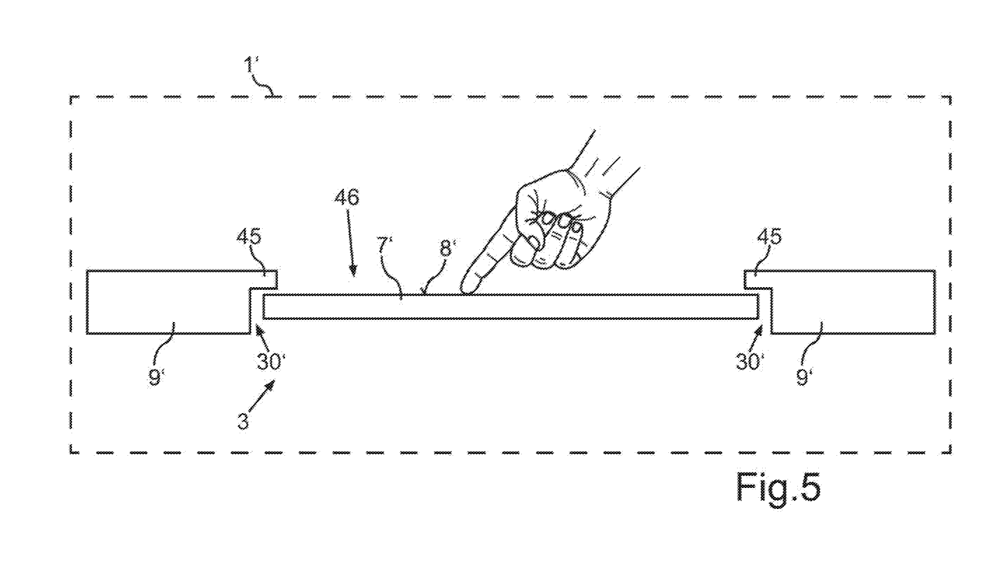

FIG. 5 shows, once again and for elucidation purposes, a motorized vehicle 1′ which has an actuation element 7′ with an operating surface 8′, as known from the related art. In the operating device 3′ shown in FIG. 5, the actuation element 7′ is not anchored by a centering element. A joint 30′ between the actuation element 7′ and housing 9′ is covered from the view of a user by cladding or tiling 45 that projects over or covers the joint 30′ so that the user cannot identify an irregular profile of a gap width of the joint 30′.

Moreover, a depression 46, in which the operating surface 8′ is arranged in lowered fashion, arises from the cladding 45.

By contrast, in the motor vehicle described herein, in which the actuation element 7 is centered by using the centering element 29 in the way shown in FIG. 1 to FIG. 4, it is possible to dispense with covering the gap of the joint 30 by way of cladding 45 and the depression 46 can be avoided by a flush arrangement of the operating surface 8 with the cladding 31 of the housing 9.

To this end, a centering rib as centering element is attached as described at the housing edge or the cladding edge of the cladding which encloses the actuation element 7. The surface 8 or the carrier element 13 is pressed by this centering rib into its initial position or rest position S1, or anchored there. As a result, a uniform circumferential gap arises, i.e., the joint dimension of the joint 30 can be kept within a predetermined tolerance range. Here, direct centering of the actuation element 7 in relation to the circumferential cladding, as illustrated in FIG. 1 and FIG. 2, has advantages from the view of tolerances since the smallest possible tolerance chain is facilitated. When the actuation element 7 is actuated, the actuation element 7 and, when necessary, the carrier element 13 is/are deflected and moved away from the centering element 29 as a result thereof. That is to say, the actuation element 7 and/or the carrier 13 is released by the actuation stroke with the deflection travel 40. This is necessary because the actuation element 7 is then made to vibrate by the actuator device 16 such that the actuation element carries out the feedback movement 39. As a result, haptic feedback for the user 4 is produced on the operating surface 8.

Overall, the example shows how centering of an operating part excited by an actuator device can be achieved.

A description has been provided with particular reference to preferred embodiments thereof and examples, but it will be understood that variations and modifications can be effected within the spirit and scope of the claims which may include the phrase “at least one of A, B and C” as an alternative expression that means one or more of A, B and C may be used, contrary to the holding in Superguide v. DIRECTV, 358 F3d 870, 69 USPQ2d 1865 (Fed. Cir. 2004).

1.-10. (canceled)

11. An operating apparatus for a motor vehicle, comprising:
a housing;
an actuation element movably mounted with respect to the housing between a rest position in a non-actuated state and a released position in an actuated state, and having a contact surface for a user;
a sensor device configured to produce a sensor signal based on a contact of the contact surface and/or an approach to the contact surface by the user;
an actuator device configured to produce a feedback movement of the actuation element based on an excitation signal;
a controller configured to produce a control signal for at least one appliance of the motor vehicle based on the sensor signal and to produce the excitation signal for the actuator device with the control signal; and
at least one centering element to block the feedback movement of the actuation element when the actuation element is disposed in the rest position, and to permit the feedback movement of the actuation element when the actuation element carries out an evasive movement in a direction aligned obliquely or perpendicular to a direction of the feedback movement when an operating force is applied on the contact surface by the user to move the actuating element from the rest position to the released position.

12. The operating apparatus as claimed in claim 11, further comprising an elastically deformably embodied restoring device to push or pull the actuation element to the rest position with a restoring force.

13. The operating apparatus as claimed in claim 11, wherein
the housing includes a cladding that surrounds the actuation element, and
the at least one centering element is disposed between the actuation element and the cladding when the actuation element is in the rest position.

14. The operating apparatus as claimed in claim 13, wherein
a joint is formed between the actuation element and the housing, and
the at least one centering element is disposed in the joint at a distance greater than zero from the contact surface.

15. The operating apparatus as claimed in claim 11, further comprising:
a carrier element movably mounted in the housing together with the actuation element; and
a support apparatus to fasten the actuation element to the carrier element,
wherein the at least one centering element is disposed between the carrier element and the housing when the actuation element is in the rest position.

16. The operating apparatus as claimed in claim 11, wherein
the actuation element includes a touchpad or a key strip, and
the sensor device is configured to indicate via the sensor signal a contact site at which the user touches the contact surface and/or approaches the contact surface.

17. The operating apparatus as claimed in claim 11, further comprising a force sensor to produce a force signal that is correlated with the operating force, and
wherein the controller is configured to produce the control signal only if the force signal indicates the operating force is greater than a predetermined threshold.

18. The operating apparatus as claimed in claim 11, wherein the at least one centering element includes an elastic material.

19. The operating apparatus as claimed in claim 11, wherein the at least one centering element includes a sliding face for the actuation element, the sliding face being disposed at an angle with respect to the direction of the evasive movement.

20. A motor vehicle, comprising:
at least one appliance; and
an operating apparatus, coupled to the at least one appliance, configured to transmit a control signal to the at least one appliance, the operating apparatus including:
a housing,
an actuation element movably mounted with respect to the housing between a rest position in a non-actuated state and a released position in an actuated state, and having a contact surface for a user,
a sensor device configured to produce a sensor signal based on a contact of the contact surface and/or an approach to the contact surface by the user,
an actuator device configured to produce a feedback movement of the actuation element based on an excitation signal,
a controller configured to produce the control signal for the at least one appliance based on the sensor signal and to produce the excitation signal for the actuator device with the control signal, and
at least one centering element to block the feedback movement of the actuation element when the actuation element is disposed in the rest position, and to permit the feedback movement of the actuation element when the actuation element carries out an evasive movement in a direction aligned obliquely or perpendicular to a direction of the feedback movement when an operating force is applied on the contact surface by the user to move the actuating element from the rest position to the released position.

21. The motor vehicle as claimed in claim 20, wherein the operating apparatus further includes:
a plate movably mounted in the housing to move together with the actuation element,
a first spring and/or rod to connect the plate with a lower portion of the actuation element, and
a second spring, disposed between the plate and the housing and connected to a lower portion of the plate, to move the plate together with the actuation element so as to move the actuation element back to the rest position with a restoring force.

22. The motor vehicle as claimed in claim 21, wherein
the at least one centering element is disposed to be in contact with a side surface of the plate when the actuation element is in the rest position such that the actuation element is indirectly held by the plate and the first spring and/or rod, and
the at least one centering element is disposed between a lower side of the actuation element and an upper side of the plate when the actuation element is in the released position.

23. The motor vehicle as claimed in claim 20, wherein
the housing includes a cladding that surrounds the actuation element,
the at least one centering element includes a rib which protrudes from the cladding toward a side surface of the actuation element in a direction transverse to the direction of the evasive movement, and
the contact surface of the actuation element is substantially flush with an upper surface of the cladding.

24. The motor vehicle as claimed in claim 23, wherein the at least one centering element is disposed below the contact surface of the actuation element and the upper surface of the cladding when the actuation element is in the rest position.

25. The motor vehicle as claimed in claim 20, wherein the at least one appliance includes at least one of an information-entertainment system, a climate control system, a telephone system, and a suspension control system.

26. The motor vehicle as claimed in claim 20, wherein
the operating apparatus further includes a force sensor to produce a force signal that corresponds to the operating force, and
the controller is configured to produce the control signal only if the force signal indicates the operating force is greater than a predetermined threshold.

27. The motor vehicle as claimed in claim 20, wherein the at least one centering element is configured as a frame or ring which surrounds the actuation element in the rest position.

28. The motor vehicle as claimed in claim 20, wherein the at least one centering element is integrally formed with the housing and protrudes from a side surface of the housing below an upper surface of the housing that is substantially flush with the contact surface of the actuating element.
